(19) United States
(12) Patent Application Publication
(10) Pub. No.: US 2012/0205662 A1
(43) Pub. Date: Aug. 16, 2012

(54) SEMICONDUCTOR DEVICE, POWER SUPPLY DEVICE, AMPLIFIER, AND METHOD OF MANUFACTURING SEMICONDUCTOR DEVICE

(75) Inventors: Norikazu Nakamura, Kawasaki (JP); Shirou Ozaki, Kawasaki (JP); Masayuki Takeda, Kawasaki (JP); Toyoo Miyajima, Kawasaki (JP); Toshihiro Ohki, Kawasaki (JP); Masahito Kanamura, Kawasaki (JP); Kenji Imanishi, Kawasaki (JP); Toshihide Kikkawa, Kawasaki (JP); Keiji Watanabe, Kawasaki (JP)

(73) Assignee: FUJITSU LIMITED, Kawasaki (JP)

(21) Appl. No.: 13/357,901

(22) Filed: Jan. 25, 2012

(30) Foreign Application Priority Data
Feb. 16, 2011 (JP) 2011-031108

(51) Int. Cl. H01L 29/20; H01L 21/336

(52) U.S. Cl. 257/76; 438/299; 257/E21.409; 257/E29.089

(57) ABSTRACT

A semiconductor device includes: a semiconductor layer formed over a substrate; an insulating film formed over the semiconductor layer; and an electrode formed over the insulating film, wherein the insulating film includes an amorphous film including carbon.

### CROSS-REFERENCE TO RELATED APPLICATIONS

This application claims the benefit of priority from Japanese Patent Application No. 2011-31108 filed on Feb. 16, 2011, the entire contents of which are incorporated herein by reference.

### FIELD

Examples relate to a semiconductor device, a power supply device, an amplifier, and a method for manufacturing a semiconductor device.

### BACKGROUND

GaN, AlN, and InN included in nitride semiconductors or materials including mixed crystals of those and the like have a wide band gap and are used for high-output electronic devices or short wavelength light emitting devices. Field effect transistors (FET), for example, a High Electron Mobility Transistor (HEMT), are used for the high-output electronic devices. An HEMT including a nitride semiconductor is used for high-output high-efficiency amplifiers, or high-power switching devices, and the like.

The HEMT having a high drain breakdown voltage and a gate breakdown voltage may include a Metal Insulator Semiconductor (MIS) structure including an insulating film to be used as a gate insulating film. Due to the MIS structure, a semiconductor device suitable for electric power application is generated.

Related art is disclosed in Japanese Laid-Open Patent Publication No. 2002-359256, Japanese Laid-Open Patent Publication No. 2008-218479, or the like.

### SUMMARY

According to one aspect of the embodiments, a semiconductor device includes: a semiconductor layer formed over a substrate; an insulating film formed over the semiconductor layer; and an electrode formed over the insulating film, wherein the insulating film includes an amorphous film including carbon.

Additional advantages and novel features of the invention will be set forth in part in the description that follows, and in part will become more apparent to those skilled in the art upon examination of the following or upon learning by practice of the invention.

### BRIEF DESCRIPTION OF THE DRAWINGS

FIG. 1 illustrates an exemplary semiconductor element;

FIG. 2A and FIG. 2B illustrate an exemplary measurement of a semiconductor element;

FIG. 3 illustrates an exemplary relationship between an applied voltage and a capacity;

FIG. 4A to FIG. 4C illustrate an exemplary insulating film;

FIG. 5 illustrates an exemplary relationship between a thickness of an amorphous carbon film and a threshold voltage variation range;

FIG. 6 illustrates an exemplary semiconductor device;

FIG. 7 illustrates an exemplary relationship between a carbon-carbon bond ratio and a film density or a plasmon peak;

FIG. 8 illustrates an exemplary plasmon peak;

FIG. 9A to FIG. 9E illustrate an exemplary method for manufacturing a semiconductor device;

FIG. 10 illustrates an exemplary film forming apparatus;

FIG. 11 illustrates an exemplary semiconductor device;

FIG. 12A and FIG. 12B illustrate an exemplary insulating film;

FIG. 13 illustrates an exemplary semiconductor device;

FIG. 14A to FIG. 14F illustrate an exemplary method for manufacturing a semiconductor device;

FIG. 15 illustrates an exemplary discrete-packaged semiconductor device;

FIG. 16 illustrates an exemplary power supply device; and

FIG. 17 illustrates an exemplary high frequency amplifier.

### DESCRIPTION OF EMBODIMENTS

Due to a reduction in on-resistance, a normally-off operation, or an increase in breakdown voltage of switching elements, a high efficiency switching element for power application using a transistor may be provided. The switching element like that may stably perform a switching operation.

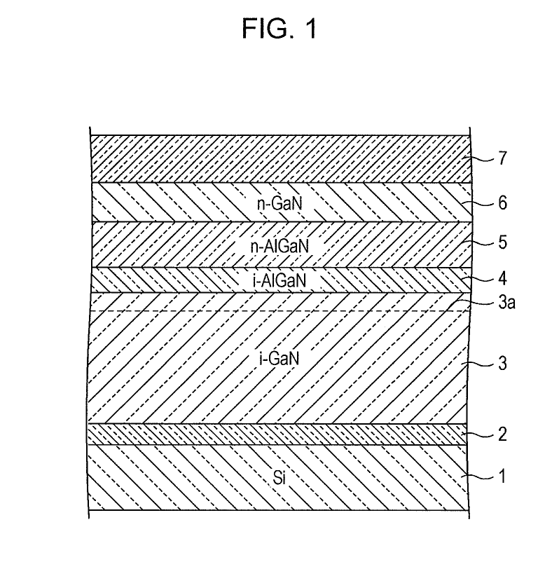

FIG. 1 illustrates an exemplary a semiconductor device. The semiconductor device illustrated in FIG. 1 may not stably perform a switching operation. The semiconductor device illustrated in FIG. 1 includes a buffer layer 2 laminated on a substrate 1 including silicon, an electron transit layer 3, a spacer layer 4, an electron supply layer 5, a cap layer 6, and an insulating film 7 formed on the cap layer 6. The electron transit layer 3, the spacer layer 4, the electron supply layer 5, and the cap layer 6 may be formed by a Metal-Organic Vapor Phase Epitaxy (MOVPE) method. In order to epitaxially grow the electron transit layer 3 and the like, the buffer layer 2 may be formed on the substrate 1. By the buffer layer 2 on the substrate 1, the electron transit layer 3 or the like is epitaxially grown on the buffer layer 2.

The electron transit layer 3 may be i-GaN having a thickness of about 3 μm. The spacer layer 4 may be i-AlGaN having a thickness of about 5 nm. The electron supply layer 5 may be n-AlGaN having a thickness of about 5 nm. The n-AlGaN may be doped with silicon (Si) as an impurity element with a concentration of 5×10¹⁸ cm⁻³. The cap layer 6 may be n-GaN having a thickness of 10 nm. The n-GaN may be doped with silicon (Si) as an impurity element with a concentration of 5×10¹⁸ cm⁻³. At the side near the electron supply layer 5 of the electron transit layer 3, a 2 dimensional electron gas (2DEG) 3a is generated. The insulating film 7 may correspond to a gate insulating film. The insulating film 7 includes a film having an aluminum oxide whose thickness is about 20 nm formed by an Atomic Layer Deposition (ALD) method.

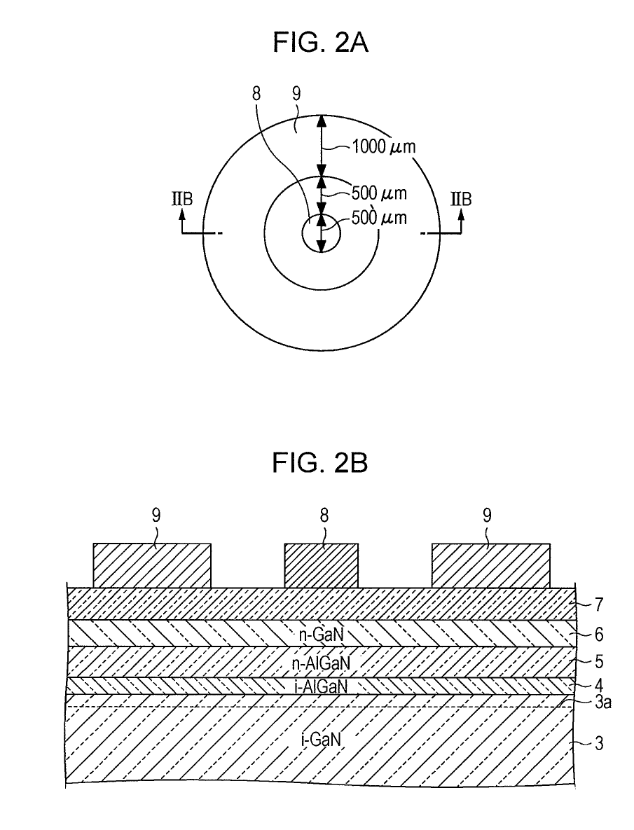

FIG. 2A and FIG. 2B illustrate an exemplary measurement of a semiconductor element. In FIG. 2, an anode electrode 8 and a cathode electrode 9 including mercury are provided on the insulating film 7. The capacity between the anode electrode 8 and the cathode electrode 9 may be measured. The anode electrode 8 may have a disk shape having a diameter of about 500 μm. The cathode electrode 9 may have a doughnut shape having an inner diameter of about 1500 μm and an outer diameter of about 2500 μm. The cathode electrode 7 may be disposed so that the center of the cathode electrode 9 matches the center of the anode electrode 8. The cathode electrode 9 may be grounded, so that a ground potential may be achieved. FIG. 2A illustrates a top view of a semiconductor element. FIG. 2B illustrates a cross sectional view taken along the dashed line IIB-IIB of FIG. 2A.

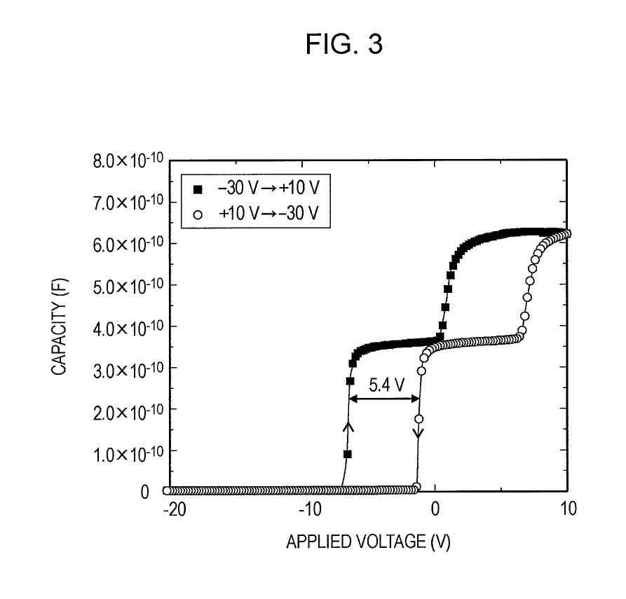

FIG. 3 illustrates an exemplary relationship between an applied voltage and a capacity. For example, FIG. 3 may illustrate the capacity detected between the anode electrode 8 and the cathode electrode 9 when the voltage applied to the anode electrode 8 varies. For example, the cathode electrode 9 is grounded, and an AC component being 100 kHz and 25 mV and superimposed on a given voltage is applied to the anode electrode 8, and the capacity is measured.

As illustrated in FIG. 3, when the voltage applied to the anode electrode 8 gradually increases from −30 V to 10V, the capacity sharply increases from 0 at around −7 V. When the voltage further increases, the capacity is substantially constant without largely varying. However, when the voltage reaches about 0 V, the capacity increases. After this, the capacity increases with an increase in the applied voltage, and gradually approaches a certain value. When the voltage applied to the anode electrode 8 gradually decreases from 10 V to −30 V, the capacity decreases with a reduction in the applied voltage. However, when the voltage reaches near 7 V, the capacity becomes substantially constant. When the voltage decreases to 0 V, the capacity may not vary. After this, with a further reduction in the applied voltage, the capacity decreases when the voltage have passed 0 V, and when the voltage reaches near −1.5 V, the capacity becomes 0, after that, when the voltage decreases, the capacity is still 0 and does not vary. For example, when the insulating film 7 of the semiconductor element illustrated in FIG. 1 includes aluminum oxide, the relationship between the applied voltage and the capacity during an increase in the voltage and the relationship between the applied voltage and the capacity during a reduction in the voltage are different from each other.

When the applied voltage increases from a low voltage, the depletion layer thickness decreases, and a capacity is produced at a time when 2DEG 3a is formed in the electron transit layer 3, and then the capacity sharply increases. When the applied voltage decreases from a high voltage, the depletion layer thickness increases, and the capacity decreases with a reduction in the 2DEG 3a. Since electrons and the like trapped at a trap level formed in the insulating film 7 affect the distribution of the 2DEG 3a, the curve during the increase in the applied voltage may be almost overlapped by a shift with the curve during the reduction in the applied voltage. For example, when a trap level is formed in the insulating film 7 so that electrons and the like are trapped, the capacity to be detected varies. The capacity detected during the increase in the voltage and the capacity detected during the reduction in the voltage may be different when substantially the same voltage is applied.

When the relationship between the voltage and the capacity varies depending on the history of the previously applied voltages, a stable switching operation may not be achieved, so that the reliability of the semiconductor device may decrease. The shift amount between a capacity curve during the increase in the voltage and a capacity curve during the reduction in the voltage may be referred to as a threshold voltage variation range. For example, when the insulating film 7 of the semiconductor device illustrated in FIG. 1 includes an aluminum oxide, the threshold voltage variation range may be about 5.4 V.

For example, when the aluminum oxide film of the insulating film 7 is an amorphous film of a compound, a trap level may be formed. When the insulating film 7 includes an amorphous film or the like which is a compound, such as an oxide or a nitride, a trap level may be formed.

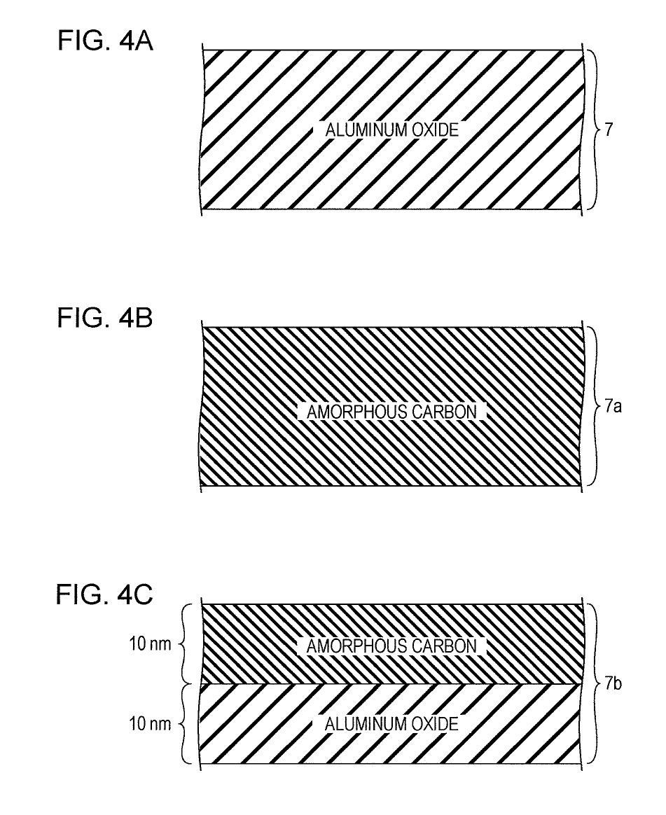

FIG. 4A to FIG. 4C illustrate an exemplary insulating film. FIG. 4A illustrates the insulating film 7 having a thickness of about 20 nm and including an aluminum oxide. FIG. 4B and FIG. 4C illustrate an insulating film including materials other than oxides and nitrides. For example, an insulating film 7a illustrated in FIG. 4B may include an amorphous carbon film. An insulating film 7b illustrated in FIG. 4C illustrates an insulating film 7b in which an amorphous carbon film and an aluminum oxide film are laminated. In the insulating film 7a illustrated in FIG. 4B, an amorphous carbon film of about 20 nm is formed. In the insulating film 7b illustrated in FIG. 4C, an aluminum oxide film of about 10 nm is formed by an ALD method, and then an amorphous carbon film of about 10 nm is formed. The amorphous carbon film may be an amorphous film including carbon as the main ingredient, and the amorphous carbon film may be formed by Filtered Cathodic Arc (FCA) which is an arc vapor deposition method.

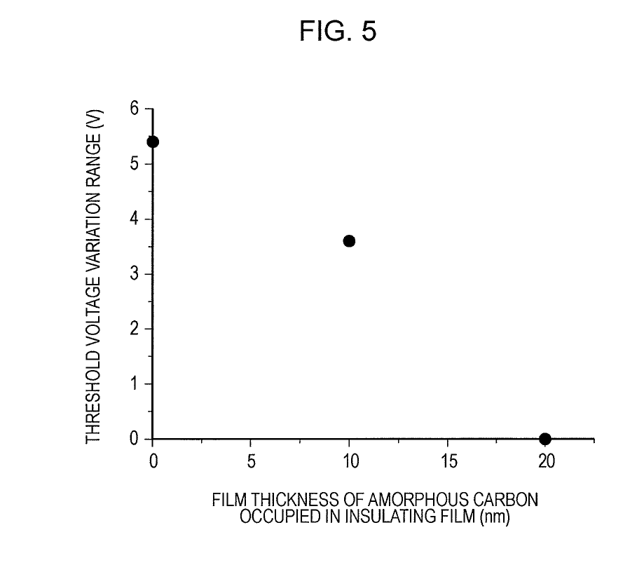

FIG. 5 illustrates an exemplary relationship between a thickness of an amorphous carbon film and a threshold voltage variation range. When the thickness of the amorphous carbon film becomes large, the threshold voltage variation range becomes small. When the insulating film is the amorphous carbon film, the threshold voltage variation range may become substantially 0.

For example, when the insulating film includes the amorphous carbon film, the threshold voltage variation range becomes small. When the entire insulating film is the amorphous carbon film, the threshold voltage variation range becomes substantially 0. When the insulating film corresponding to the gate insulating film includes the amorphous carbon film, a switching operation may be stably performed. For example, when the insulating film corresponding to the gate insulating film is partially or entirely the amorphous carbon film, the switching operation may be stably performed, so that a highly reliable semiconductor device may be provided.

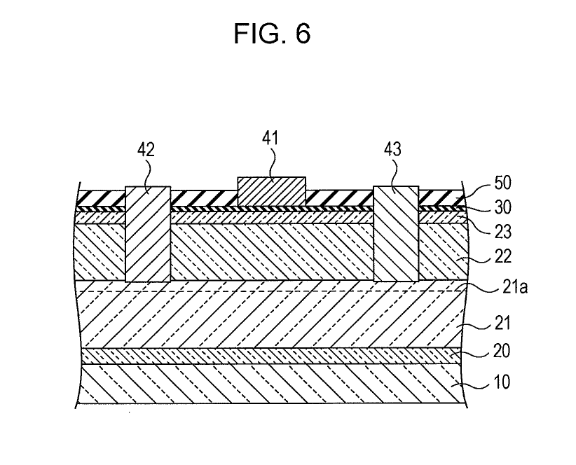

FIG. 6 illustrates an exemplary semiconductor device. The semiconductor device illustrated in FIG. 6 may be an HEMT. The semiconductor device includes a buffer layer 20 formed on the substrate 10 including a semiconductor or the like and an electron transit layer 21, an electron supply layer 22, and a cap layer 23 including a semiconductor layer laminated on the buffer layer 20 by epitaxial growth. On the cap layer 23, an insulating film 30 is formed. On the insulating film 30, a gate electrode 41 is formed. A source electrode 42 and a drain electrode 43 are coupled to the electron transit layer 21. On the exposed insulating film 30, a protective film 50 including an insulator is formed.

The substrate 10 may include a Si substrate, a SiC substrate, a sapphire (Al₂O₃) substrate, or the like. For example, the substrate 10 is a Si substrate and the buffer layer 20 is formed on the substrate. When the substrate 10 includes other materials, the buffer layer 20 may not be formed. The electron transit layer 21 may be i-GaN, the electron supply layer 22 may be n-AlGaN, and the cap layer 23 may be n-GaN. A two-dimensional electron gas (2DEG) 21a is formed at the side near the electron supply layer 22 of the electron transit layer 21. A non-illustrated spacer layer may be formed between the electron transit layer 21 and the electron supply layer 22.

The gate electrode 41, the source electrode 42, and the drain electrode 43 may include metal materials. The insulating film 30 to be a gate insulating film may include an amorphous carbon film having a thickness of 20 nm. The protective film 50 may include an aluminum oxide (Al₂O₃) film formed by a plasma ALD.

The amorphous carbon film as the insulating film 30 may be an amorphous film including carbon as the main ingredient, and may be referred to as Diamond Like Carbon (DLC). The amorphous carbon film has high density, high insulation properties, and high surface smoothness. The hydrogen content in the amorphous carbon film having high insulating properties, high density, or the like may be reduced, and the amorphous carbon film may be a diamond like film. For example, the film density of the amorphous carbon film may be high and the sp3 content may be higher than the sp2 content in the carbon-carbon bond of the amorphous carbon film. The amorphous carbon film in a state where the sp3 content is higher than the sp2 content in the carbon-carbon bond becomes a film in a state close to a high-density diamond. Therefore, the formation of a trap level or the like may be reduced and the threshold voltage variation range may become small. For example, the insulating film 30 including the amorphous carbon film may stably perform a switching operation.

The carbon-carbon bond includes bonding manners sp2 and sp3. Graphite is formed with the carbon-carbon bond sp2, and a diamond is formed with the carbon-carbon bond sp3. When the amorphous carbon film is further a diamond-like film, the sp3 bond content is higher than the sp2 bond content. For example, the carbon-carbon bond content may be sp2≦sp3.

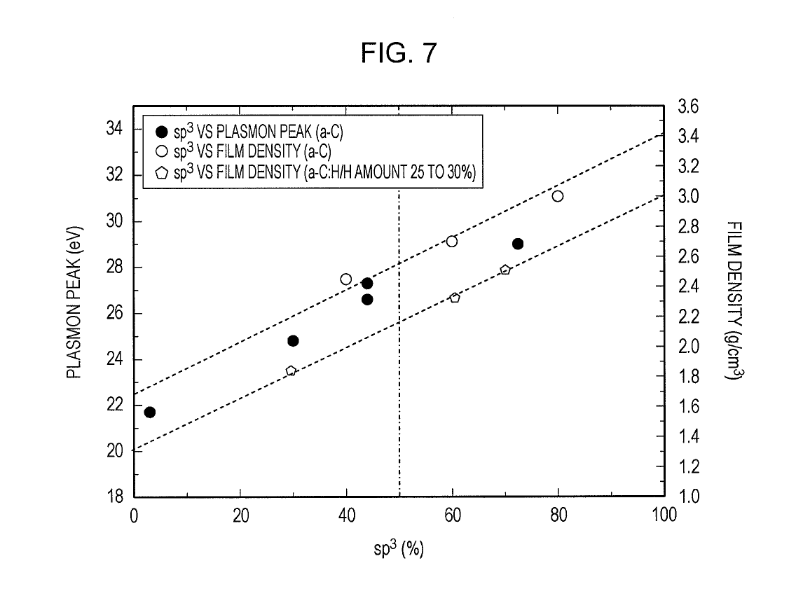

FIG. 7 illustrates an exemplary relationship between a carbon-carbon bond ratio and a film density or a plasmon peak. As illustrated in FIG. 7, the carbon-carbon bond sp3 ratio and the film density of the amorphous carbon film have a correlation, and when the carbon-carbon bond sp3 ratio becomes high, the film density also becomes high. The carbon-carbon bond sp3 ratio and the plasmon peak of the amorphous carbon film have a correlation, and when the carbon-carbon bond sp3 ratio becomes high, the plasmon peak also becomes high. The amorphous carbon film where carbon-carbon bond sp3 ratio is 50% or more, for example, The amorphous carbon film where the sp3 bond ratio is higher than the sp2 bond ratio and hydrogen is hardly included, may have a film density of 2.6 g/cm³ or more and a plasmon peak may be 28 eV or more. The film density may be calculated based on the results obtained by Rutherford backscattering spectroscopy in the amorphous carbon film formed on the silicon substrate and the film thickness obtained by cross section length measuring by Transmission Electron Microscope (TEM).

When the film density of the amorphous carbon film is 2.6 g/cm³ or more and the plasmon peak of the film is 28 eV or more, the amorphous carbon film may be formed by an FCA method of an arc vapor deposition method. For example, the film density of the amorphous carbon film formed by the FCA method may be 3.2 g/cm³. The density of diamond may be 3.56 g/cm³. The film densities of the amorphous carbon film may be 2.6 g/cm³ or more and 3.56 g/cm³ or lower. The hydrogen content of the amorphous carbon film formed by the FCA method is lower than the hydrogen content of the amorphous carbon film formed by CVD. The hydrogen content in the amorphous carbon film formed by the FCA method may be 1 atm % or lower. The highest film density of the amorphous carbon film including hydrogen formed by Chemical Vapor Deposition (CVD) may be lower than about 2.6 g/cm³.

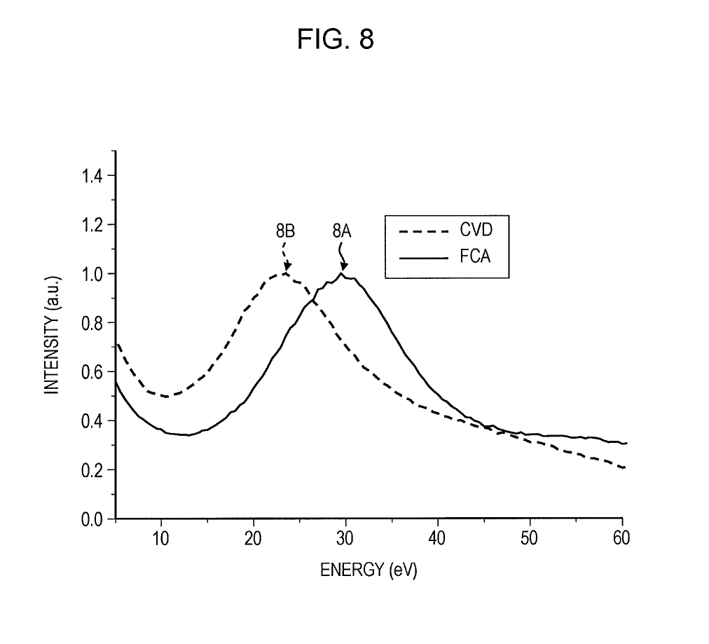

FIG. 8 illustrates an exemplary plasmon peak. FIG. 8 illustrates the plasmon peaks of amorphous carbon films formed by the FCA method or the CVD method. The plasmon peak 8A of the amorphous carbon film formed by the FCA method may be about 30 eV and is 28 eV or more. The plasmon peak 8B of the film formed by the CVD method may be about 23 eV and may be lower than 28 eV. The plasmon peak of the film formed by the FCA method may be 28 eV or more. The insulating film 30 may be an amorphous carbon film formed by the FCA method. The carbon-carbon bond of the amorphous carbon film may be sp2≦sp3, the density may be 2.6 g/cm³ or more and 3.56 g/cm³ or lower, and the plasmon peak may be 28 eV or more.

The thickness of the amorphous carbon film formed as the insulating film 30 may be 2 nm or more and 200 nm or lower, for example, 10 nm or more and 30 nm or lower. When the amorphous carbon film covers the entire surface, the thickness of the amorphous carbon film may be at least several atom layers or more. An amorphous carbon film whose thickness is lower than 2 nm may not be able to cover the entire surface. For example, the thickness of the amorphous carbon film may be 10 nm or more as illustrated in FIG. 5. Since the stress of the amorphous carbon film is high, film separation may occur due to the stress in an amorphous carbon film whose thickness exceeds 30 nm. The thickness of the amorphous carbon film may be 30 nm or lower.

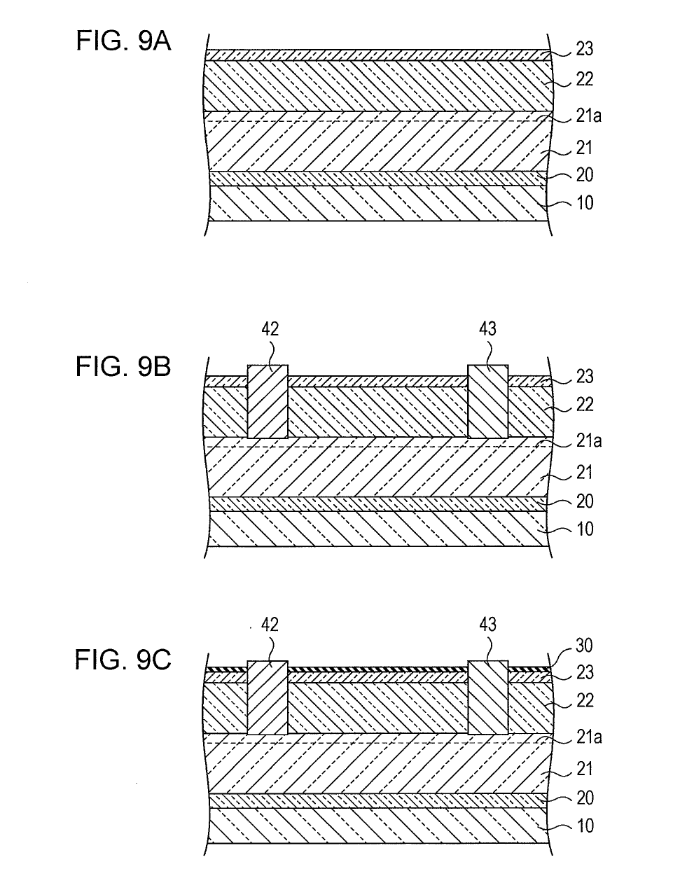

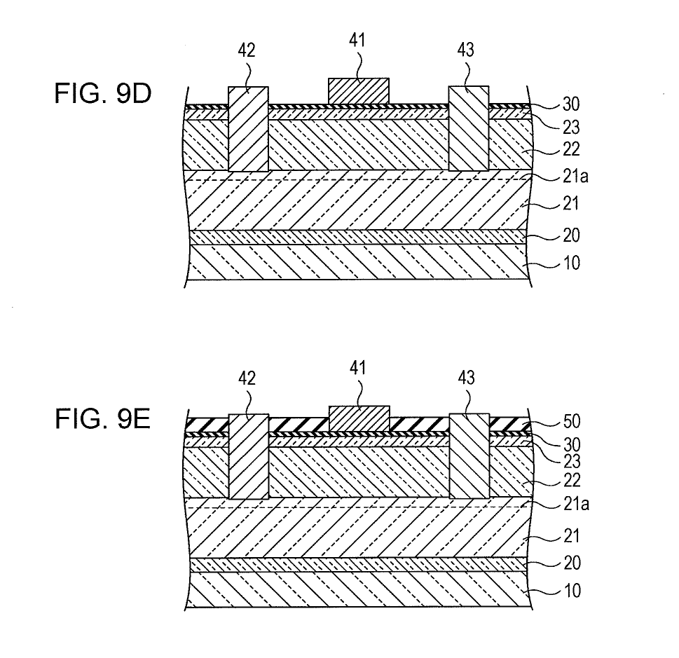

FIG. 9A to FIG. 9E illustrate an exemplary method for manufacturing a semiconductor device.

As illustrated in FIG. 9A, the buffer layer 20 is formed on the substrate 10 and a semiconductor layer including the electron transit layer 21, the electron supply layer 22, the cap layer 23, and the like is formed on the buffer layer 20 by epitaxial growth by Metal-Organic Vapor Phase Epitaxy (MOVPE) or the like. The substrate 10 may be a substrate including Si, SiC, sapphire (Al₂O₃), or the like. On the substrate 10, the buffer layer 20 may be formed in order to epitaxially grow the electron transit layer 21 and the like. The buffer layer 20 may be a non-doped i-AlN layer having a thickness of about 0.1 μm, for example. The electron transit layer 21 may be a non-doped i-GaN layer having a thickness of about 3 μm. The electron supply layer 22 may be an n-Al_{0.25}Ga_{0.75}N layer having a thickness of about 30 nm, which may be doped with Si as an impurity element with a concentration of 5×10¹⁸ cm⁻³. The cap layer 23 may be an n-GaN layer having a thickness of about 10 nm, which may be doped with Si as an impurity element with a concentration of 5×10¹⁸ cm⁻³. The semiconductor layer may be formed by crystal growth, such as Molecular Beam Epitaxy (MBE).

As illustrated in FIG. 9B, the source electrode 42 and the drain electrode 43 are formed. For example, a photoresist is applied onto the cap layer 23, followed by exposure by an exposing apparatus and development, thereby forming a non-illustrated resist pattern having an opening portion in a region where the source electrode 42 and the drain electrode 43 are to be formed. Dry etching, such as Reactive Ion Etching (RIE) using chlorine gas, is performed to remove the cap layer 23 and the electron supply layer 22 in a region where the resist pattern is not formed, so that the surface of the electron transit layer 21 is exposed. In the dry etching, chlorine gas of about 30 sccm is introduced as an etching gas into a chamber, the pressure in the chamber is set to about 2 Pa, and RF power of 20 W is applied. A metal film including a Ta/Al laminated film or the like is formed by vacuum deposition or the like, and the metal film formed on the resist pattern is lifted-off with the resist pattern and removed by immersion in an organic solvent or the like. The source electrode 42 and the drain electrode 43 are formed in a region where the resist pattern is not formed. After lifting-off, heat treatment with a temperature of 550° C. is performed, for example, and ohmic contact is achieved. The resist pattern in the dry etching may be used for the resist pattern in the lifting-off, however, the dry etching and the lifting-off may be separately carried out.

As illustrated in FIG. 9C, the insulating film 30 corresponding to a gate insulating film is formed on the cap layer 23. The insulating film 30 may be formed by growing an amorphous carbon film by the FCA method. For example, by using a graphite target as a raw material, setting an arc current to 70 A and setting an arc voltage to 26 V, an amorphous carbon film having a thickness of about 20 nm may be formed by the FCA method.

As illustrated in FIG. 9D, the gate electrode 41 is formed. For example, a photoresist is applied onto the insulating layer 30, followed by exposure by an exposing apparatus and development, thereby forming a non-illustrated resist pattern having an opening portion in a region where the gate electrode 41 is to be formed. A metal film, for example, Ni film having a thickness of about 10 nm or Au film having a thickness of about 300 nm, is formed on the entire surface by vacuum deposition, and the metal film formed on the resist pattern is lifted-off with the resist pattern and removed by immersion in an organic solvent or the like. The gate electrode 41 including Ni/Au is formed in a given region on the insulating film 30.

As illustrated in FIG. 9E, the protective film 50 is formed on the insulating film 30. The protective film 50 may include an aluminum oxide film formed by the ALD method, an amorphous carbon film formed by the FCA method, a silicon nitride film formed by the plasma CVD method, or a laminate of these films, for example.

Through the above-described processes, a transistor may be formed. The semiconductor layer may include GaN and AlGaN and may also include a nitride semiconductor, such as InAlN or InGaAlN.

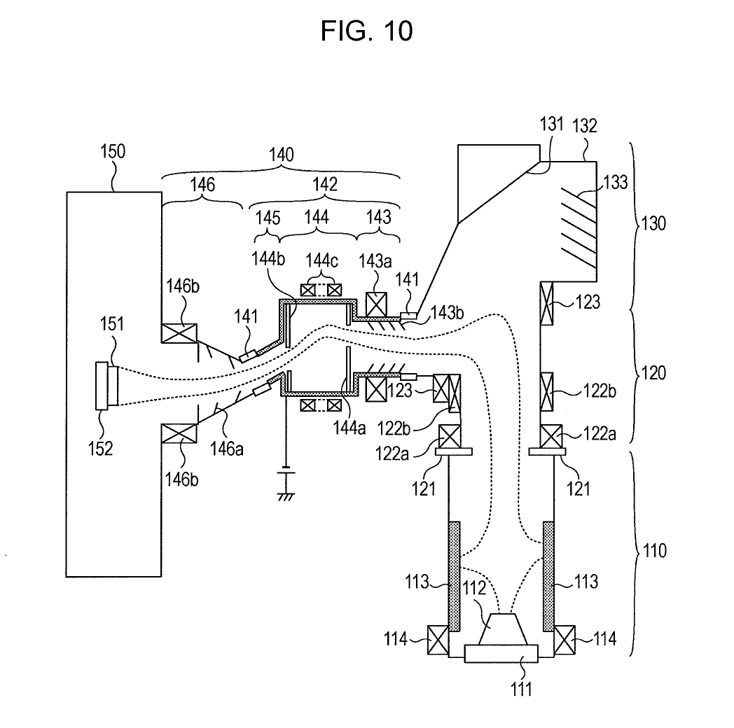

FIG. 10 illustrates an exemplary film forming apparatus. The film forming apparatus illustrated in FIG. 10 may be an FCA film forming apparatus for use in the FCA method. The FCA film forming apparatus includes a plasma generating portion 110, a plasma separating portion 120, a particle trapping portion 130, a plasma carrying portion 140, and a film forming chamber 150. The plasma generating portion 110, the plasma separating portion 120, and the particle trap portion 130 may have a cylindrical shape and may be associated in this order. The plasma carrying portion 140 also has a cylindrical shape. One end of the plasma carrying portion 140 is almost perpendicularly coupled to the plasma separating portion 120 and the other end of the plasma carrying portion is coupled to the film forming chamber 150. Inside the film forming chamber 150, a stage 152 for disposing a substrate 151 or the like serving as a film forming target is provided.

An insulating plate 111 is provided on the lower end portion of the case of the plasma generating portion 110, and a graphite serving as a target (cathode) 112 is provided on the insulating plate 111. On the periphery of the lower end portion of a case of the plasma generating portion 110, a cathode coil 114 is provided. On the inner wall surface of the case, an anode 113 is provided. When the amorphous carbon film is formed, arc discharge occurs by the application of a given voltage between the target 112 and the anode 113 from a non-illustrated power source, so that plasma is formed above the target 112. In the cathode coil 114, a magnetic field for stabilizing the arc discharge is produced by supplying a given current from another non-illustrated power supply. Due to the arc discharge, carbon, which is the target 112 of graphite, evaporates and is supplied into the plasma as ions of film forming materials.

An insulating ring 121 is provided on the boundary portion between the plasma generating portion 110 and the plasma separating portion 120. The case of the plasma generating portion 110 and the case of the plasma separating portion 120 are electrically separated by the insulating ring 121. On the periphery of the plasma separating portion 120, guide coils 122a and 122b are provided which generate a magnetic field for moving the plasma formed in the plasma generating portion 110 in a given direction while converging the plasma to the central portion of the case. In the vicinity of the associating portion of the plasma separating portion 120 and the plasma carrying portion 140, an oblique magnetic field generating coil 123 is provided which generates a magnetic field which substantially perpendicularly deflects the plasma moving direction.

Particles generated in the plasma generating portion 110 enter and go straight into the particle trapping portion 130 with being hardly affected by the magnetic field in the plasma separating portion 120. On the upper end of the particle trapping portion 130, a reflector 131 which reflects the particles in a transverse direction and a particle capturing portion 132 which capture the particles reflected by the reflector 131 are provided. In the particle capturing portion 132, plural fins 133 are disposed obliquely to the inside of the case. The particles entering the particle capturing portion 132 are repeatedly reflected by the fins 133 to lose the kinetic energy. Eventually, the particles adhere to the fins 133 or the wall surface of the case of the particle capturing portion 132 and are captured.

The plasma separated from the particles in the plasma separating portion 120 enters the plasma carrying portion 140. The plasma carrying portion 140 is divided into a negative voltage applying portion 142 and an associating portion 146. An insulating ring 141 is provided between the negative voltage applying portion 142 and the plasma separating portion 120 and between the negative voltage applying portion 142 and the associating portion 146. The plasma separating portion 120 and the negative voltage applying portion 142 are electrically separated and the associating portion 146 and the negative voltage applying portion 142 are electrically separated.

The negative voltage applying portion 142 is divided into an inlet portion 143 at the side of the plasma separating portion 120, an outlet portion 145 at the side of the associating portion 146, and an intermediate portion 144 between the inlet portion 143 and the outlet portion 145. On the periphery of the inlet portion 143, 143a is provided which generates a magnetic field for moving the plasma to the side of the film forming chamber 150 while converging the plasma. Inside the inlet portion 143, a plurality of fins 143b which capture the particles entering the inlet portion 143 are provided obliquely to the case inner surface.

Apertures 144a and 144b each having an opening portion for regulating the flow path of the plasma are provided at the inlet portion 143 side and the outlet portion 145 side, respectively, of the intermediate portion 144. On the periphery of the intermediate portion 144, a guide coil 144c is provided which generates a magnetic field for deflecting the plasma moving direction.

The diameter of the associating portion 146 may become gradually larger from the negative voltage applying portion 142 side to the film forming chamber 150. Also inside the associating portion 146, a plurality of fins 146a are provided. On the periphery of the boundary portion of the associating portion 146 and the film forming chamber 150, a guide coil 146b is provided which moves the plasma to the film forming chamber 150 side while converging the plasma.

In the FCA film forming apparatus, the plasma generating portion 110 discharges arc and generates plasma including carbon ions. The plasma reaches the substrate 151 and the like while the oblique magnetic field generating coil 123 and the like are removing components which become particles. Therefore, an amorphous carbon film is formed on the substrate 151 and the like.

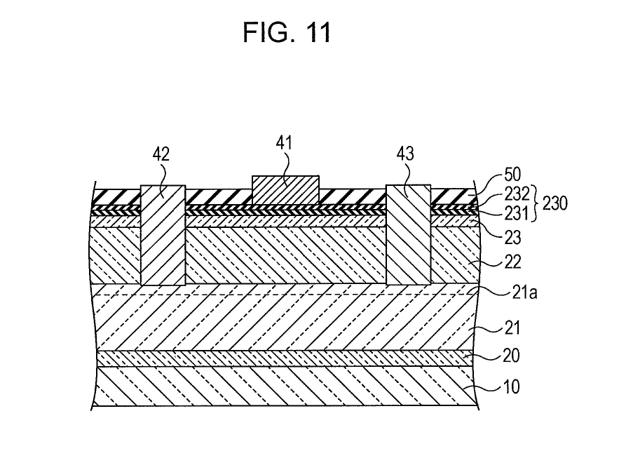

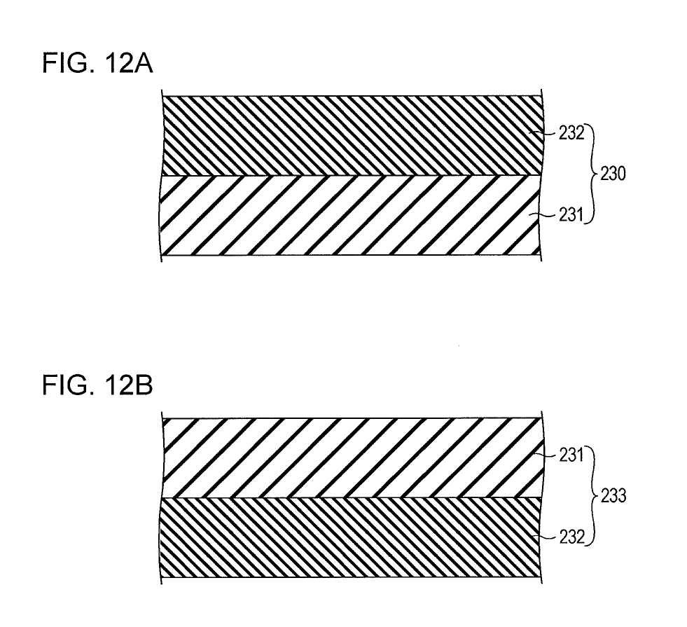

FIG. 11 illustrates an exemplary semiconductor device. The semiconductor device illustrated in FIG. 11 includes an insulating film 230, which includes a laminated structure of an aluminum oxide film 231 and an amorphous carbon film 232, for example, the insulating film 230 in which the amorphous carbon film 232 is formed on the aluminum oxide film 231, in place of the insulating film 30 including the amorphous carbon film of the semiconductor device illustrated in FIG. 6. An aluminum oxide film 231 having a thickness of about 10 nm may be formed by the ALD method by using trimethyl aluminum (TMA) and pure water (H₂O) and setting the substrate temperature to 300° C. By the above-described FCA method, an amorphous carbon film 232 having a thickness of about 10 nm may be formed. FIG. 12A and FIG. 12B each illustrate an exemplary insulating film. FIG. 12A may be an enlarged view of the insulating film 230 illustrated in FIG. 11.

In the gate insulating film corresponding to the insulating film 230, two different material films are laminated. Therefore, the gate leakage current may be reduced. For example, the gate leakage current may decrease by the lamination of an aluminum oxide film whose insulation properties are higher than those of the amorphous carbon film, as compared with the insulating film including only the amorphous carbon film.

In order to reduce the threshold voltage variation range, the thickness of the amorphous carbon film 232 may be equal to or larger than that of the aluminum oxide film 231 as illustrated in FIG. 5. The thickness of the amorphous carbon film 232 may be 10 nm or more.

In place of the aluminum oxide film 231, a hafnium oxide film or a silicon nitride film may be formed. As illustrated in FIG. 12B, by forming the amorphous carbon film 232 and forming the aluminum oxide film 231 on the amorphous carbon film 232, the insulating film 233 or the insulating film 230 may be formed. Other elements may be substantially the same as or similar to the elements illustrated in FIG. 9.

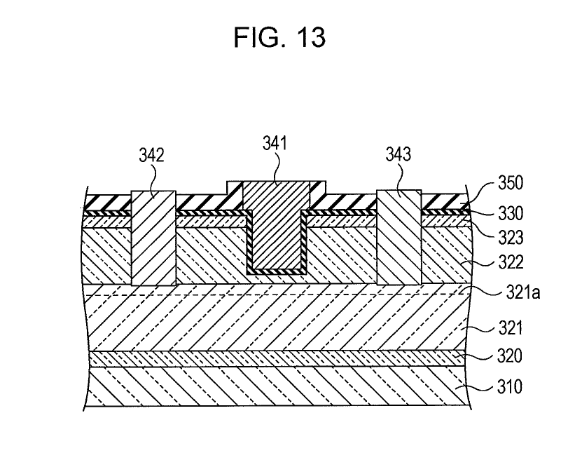

FIG. 13 illustrates an exemplary semiconductor device. The semiconductor device illustrated in FIG. 13 may be an HEMT. The semiconductor device includes a buffer layer 320 formed on a substrate 310 including a semiconductor and the like and an electron transit layer 321, an electron supply layer 322, and a cap layer 323 laminated on the buffer layer 320 by epitaxial growth. A source electrode 342 and a drain electrode 343 are coupled to the electron transit layer 321. A gate electrode 341 is formed through an insulating film 330 in an opening portion formed by partially removing the cap layer 323 and the electron supply layer 322. The insulating film 330 is also formed on the cap layer 323, and a protective film 350 including an insulator is formed on the insulating film 330.

The substrate 310 may include a Si substrate, a SiC substrate, a sapphire (Al₂O₃) substrate, or the like. When the substrate 310 is a Si substrate, the buffer layer 320 is formed. When the substrate 310 includes other materials, the buffer layer 320 may not be formed. The electron transit layer 321 may be i-GaN, the electron supply layer 322 may be n-AlGaN, and the cap layer 323 may be n-GaN. A two-dimensional electron gas (2DEG) 321a is formed at the side near the electron supply layer 322 of the electron transit layer 321. Between the electron transit layer 321 and the electron supply layer 322, a non-illustrated spacer layer may be formed.

The gate electrode 341, the source electrode 342, and the drain electrode 343 include metal materials. The insulating film 330 corresponding to the gate insulating film includes an amorphous carbon film having a thickness of 20 nm, for example. The protective film 350 is formed by forming an aluminum oxide (Al₂O₃) film by the plasma ALD.

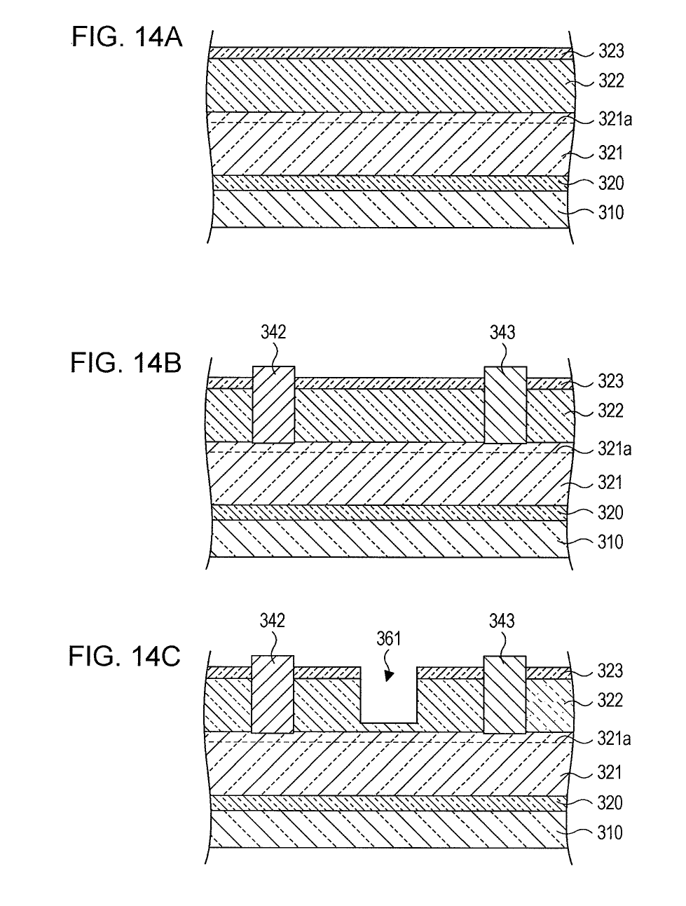

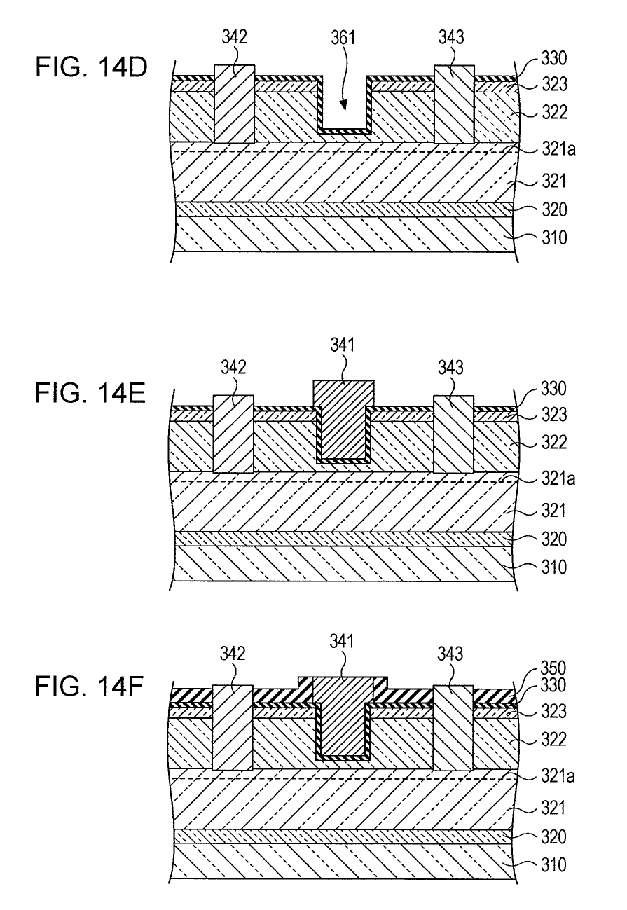

FIG. 14A to FIG. 14F illustrate an exemplary method for manufacturing a semiconductor device.

As illustrated in FIG. 14A, the buffer layer 320 is formed on the substrate 310. On the buffer layer 320, semiconductor layers of the electron transit layer 321, the electron supply layer 322, and the cap layer 323 are formed by epitaxial growth, such as MOVPE. The substrate 310 may include Si, SiC, sapphire (Al₂O₃), or the like. In order to form the electron transit layer 321 and the like by epitaxial growth, the buffer layer 320 is formed on the substrate 310. The buffer layer 320 may be a non-doped i-AlN layer having a thickness of about 0.1 μm, for example. The electron transit layer 321 may be a non-doped i-GaN layer having a thickness of about 3 μm. The electron supply layer 322 may be an n-Al_{0.25}Ga_{0.75}N layer having a thickness of about 30 nm where Si is doped as an impurity element with a concentration of 5×10¹⁸ cm⁻³. The cap layer 323 may be an n-GaN layer having a thickness of about 10 nm where Si is doped as an impurity element with a concentration of 5×10¹⁸ cm⁻³.

As illustrated in FIG. 14B, the source electrode 342 and the drain electrode 343 are formed. For example, a photoresist is applied onto the cap layer 323, followed by exposure by an exposing apparatus and development, thereby forming a non-illustrated resist pattern having opening portions in regions where the source electrode 342 and the drain electrode 343 are to be formed. Dry etching, such as RIE using chlorine gas, is performed to remove the cap layer 23 and the electron supply layer 22 in a region where the resist pattern is not formed, so that the surface of the electron transit layer 21 is exposed. A metal film including a Ta/Al laminated film or the like is formed by vacuum deposition or the like, and the metal film formed on the resist pattern is lifted-off with the resist pattern by immersion in an organic solvent or the like. The source electrode 342 and the drain electrode 343 are formed in a region where the resist pattern is not formed. After lifting-off, ohmic contact is achieved by heat treatment at a temperature of 550° C.

As illustrated in FIG. 14C, an opening portion 361 is formed. For example, a photoresist is applied onto the cap layer 323, followed by exposure by an exposing apparatus and development, thereby forming a non-illustrated resist pattern having an opening portion in a region where the opening portion 361 is to be formed. Gas including chlorine is introduced using the resist pattern as a mask, and dry etching by RIE or the like is performed. The cap layer 323 and the electron supply layer 322 in the region where the resist pattern is not formed are partially removed, and the opening portion 361 is formed. The resist pattern is removed.

As illustrated in FIG. 14D, the insulating film 330 is formed on the cap layer 323 on the inner surface of the opening portion 361. The insulating film 330 is formed by the formation of the amorphous carbon film by the FCA method. For example, by using a graphite target as a raw material, setting an arc current to 70 A, and setting an arc voltage to 26 V, an amorphous carbon film having a thickness of about 20 nm is formed by the FCA method, and the insulating film 330 is formed.

As illustrated in FIG. 14E, the gate electrode 341 is formed. For example, a non-illustrated lower resist, for example, PMGI (trade name) manufactured by U.S. MicroChem. Corp. and a non-illustrated upper resist, for example, PFI32-A8 (trade name) manufactured by Sumitomo Chemical Co., Ltd., are individually formed on the insulating film 330 by the application by a spin coat method or the like. Exposure by an exposing apparatus and development are performed, whereby an opening having a diameter of about 0.8 μm is formed in the upper resist in a region including a portion where the opening portion 361 is formed. The lower resist is wet etched by an alkaline developer using the upper resist as a mask. Metal films, for example, Ni film having a thickness of about 10 nm and Au film having a thickness of about 300 nm, are formed by vacuum deposition on the entire surface, and lifting-off is performed using a warmed organic solvent, whereby the metal film formed on the upper resist is removed with the lower resist and the upper resist. The gate electrode 341 including Ni/Au is formed in the opening portion 361 through the insulating film 330.

As illustrated in FIG. 14F, the protective film 350 is formed on the insulating film 330. The protective film 350 may include an aluminum oxide film formed by the ALD method, an amorphous carbon film formed by the FCA method, a silicon nitride film formed by the plasma CVD method, or a laminated structure of these films, for example.

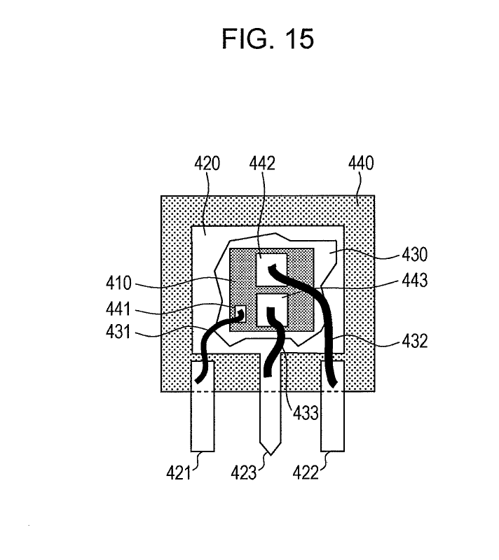

FIG. 15 illustrates an exemplary discrete-packaged semiconductor device. The semiconductor device may be a semiconductor device illustrated in FIG. 6, FIG. 11, or FIG. 13. FIG. 15 schematically illustrates the inside of the discrete-packaged semiconductor device, in which the arrangement of electrodes and the like may be different from the electrode arrangement of FIG. 6, FIG. 11, or FIG. 13.

For example, the semiconductor device illustrated in FIG. 6 or FIG. 11 or FIG. 13 is cut by dicing or the like, whereby an HEMT semiconductor chip 410 including a GaN-based semiconductor material is formed. The semiconductor chip 410 is fixed by a die attach adhesive 430, such as a solder, on a lead frame 420.

A gate electrode 441 is coupled to a gate lead 421 through a bonding wire 431. A source electrode 442 is coupled to a source lead 422 through a bonding wire 432. A drain electrode 443 is coupled to a drain lead 423 through a bonding wire 433. The bonding wires 431, 432, and 433 may include metal materials, such as Al. The gate electrode 441 may be a gate electrode pad, and is coupled to the gate electrode 41 or 341 of FIG. 6, FIG. 11, or FIG. 13. The source electrode 442 may be a source electrode pad, and is coupled to the source electrode 42 or 342. The drain electrode 443 may be a drain electrode pad, and is coupled to the drain electrode 43 or 343.

Resin sealing is performed using a mold resin 440 by a transfer mold method. A semiconductor device in which an HEMT including a GaN-based semiconductor material is discrete-packaged is formed.

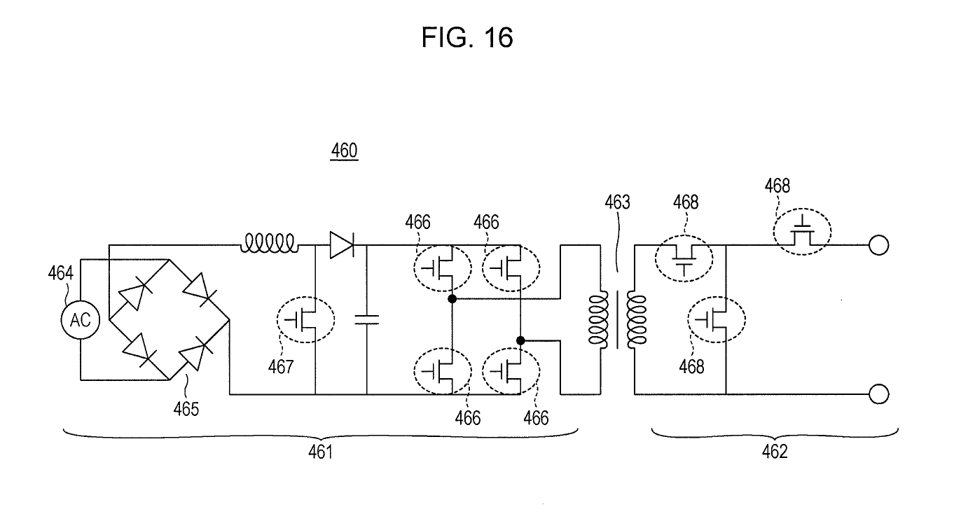

FIG. 16 illustrates an exemplary power supply device. A power supply device 460 includes a high-pressure primary circuit 461, a low-pressure secondary circuit 462, and a transformer 463 disposed between the primary circuit 461 and the secondary circuit 462. The primary circuit 461 includes an AC power supply 464, a bridge rectifier circuit 465, a plurality of switching elements 466, for example, four switching elements, and one switching element 467. The secondary circuit 462 includes a plurality of switching elements 468, for example, three switching elements. The semiconductor device of FIG. 6, FIG. 11, or FIG. 13 may be used as the switching elements 466 and 467 of the primary circuit 461. The switching elements 466 and 467 of the primary circuit 461 may be normally-off semiconductor devices. The switching elements 468 at the secondary circuit 462 side may include a metal insulator semiconductor field effect transistor (MISFET) including silicon.

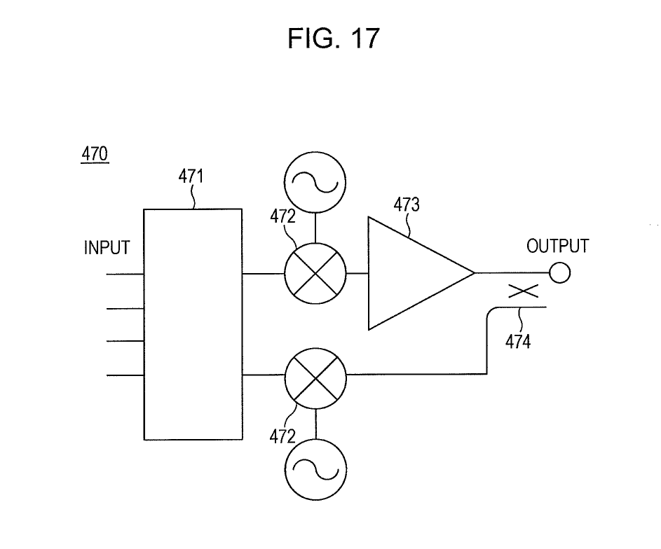

FIG. 17 illustrates an exemplary high frequency amplifier. A high frequency amplifier 470 may be applied to a power amplifier for base stations of cellular phones, for example. The high frequency amplifier 470 includes a digital predistortion circuit 471, a mixer 472, a power amplifier 473, and a directional coupler 474. The digital predistortion circuit 471 compensates the nonlinear distortion of an input signal. The mixer 472 mixes the input signal in which the nonlinear distortion has been compensated and an alternating current signal. The power amplifier 473 amplifies the input signal mixed with the alternating current signal. The power amplifier 473 may include the semiconductor device of FIG. 6, FIG. 11, or FIG. 13. The directional coupler 474 monitors input signals or output signals. For example, the mixer 472 may mix output signals with alternating current signals, and send the mixed signals to the digital predistortion circuit 471 based on switching of the switch.

Example embodiments of the present invention have now been described in accordance with the above advantages. It will be appreciated that these examples are merely illustrative of the invention. Many variations and modifications will be apparent to those skilled in the art.

1. A semiconductor device, comprising:
a semiconductor layer formed over a substrate;
an insulating film formed over the semiconductor layer; and
an electrode formed over the insulating film,
wherein the insulating film includes an amorphous film including carbon.

2. The semiconductor device according to claim 1, wherein the insulating film is a laminated film of the amorphous film and a film including an oxide or a nitride.

3. The semiconductor device according to claim 2, wherein the film including an oxide or a nitride is an aluminum oxide film.

4. The semiconductor device according to claim 2, wherein a thickness of the amorphous film is equal to or larger than a thickness of the film including an oxide or a nitride.

5. The semiconductor device according to claim 1, wherein a thickness of the amorphous film is 10 nm or more.

6. The semiconductor device according to claim 1, wherein a carbon-carbon bond ratio in the amorphous film is sp2≦sp3.

7. The semiconductor device according to claim 1, wherein a density of the amorphous film is 2.6 g/cm³ or more and 3.56 g/cm³ or lower.

8. The semiconductor device according to claim 1, wherein a plasmon peak based on the carbon in the amorphous film is 28 eV or higher.

9. The semiconductor device according to claim 1, wherein a hydrogen content in the amorphous film is 1 atm % or lower.

10. The semiconductor device according to claim 1, wherein
the semiconductor layer includes a first semiconductor layer and a second semiconductor layer formed over the first semiconductor layer; and
a source electrode and a drain electrode which are formed in contact with the first semiconductor layer or the second semiconductor layer are provided.

11. The semiconductor device according to claim 10, further comprising,
an opening portion in the second semiconductor layer,
wherein the insulating film is formed over an inner surface of the opening portion; and
the electrode is formed in the opening portion through the insulating film.

12. The semiconductor device according to claim 10, wherein the first semiconductor layer includes GaN.

13. The semiconductor device according to claim 10, wherein the second semiconductor layer includes AlGaN.

14. A method for manufacturing a semiconductor device, comprising:
forming a semiconductor layer over a substrate;
forming an insulating film including an amorphous film including carbon over the semiconductor layer; and
forming an electrode over the insulating film.

15. The method for manufacturing a semiconductor device according to claim 14, comprising:
forming the amorphous film; and
forming a film including an oxide or a nitride.

16. The method for manufacturing a semiconductor device according to claim 14, comprising:
forming a first semiconductor layer;
forming a second semiconductor layer over the first semiconductor layer: and
forming a source electrode and a drain electrode in contact with the first semiconductor layer or the second semiconductor layer.

17. The method for manufacturing a semiconductor device according to claim 14, comprising:
forming an opening portion in a second semiconductor layer;
forming the insulating film over the second semiconductor layer and an inner surface of the opening portion; and
forming the electrode in the opening portion through the insulating film.

18. The method for manufacturing a semiconductor device according to claim 14, wherein the amorphous film is formed by an arc vapor deposition method.
